(19) United States
(12) Patent Application Publication
(10) Pub. No.: US 2016/0260675 A1
(43) Pub. Date: Sep. 8, 2016

(54) SLOTTED SUBSTRATE FOR DIE ATTACH INTERCONNECTS

(71) Applicant: GLOBALFOUNDRIES Inc., Grand Cayman (KY)

(72) Inventor: Ivan Junju HUANG, Pleasanton, CA (US)

(21) Appl. No.: 14/637,448

(22) Filed: Mar. 4, 2015

(51) Int. Cl. H01L 23/00; H01L 21/3065; H01L 21/263; H01L 21/304

(52) U.S. Cl. CPC H01L 23/562; H01L 21/3043; H01L 21/3065; H01L 21/2633

(57) ABSTRACT

A method of forming slots into a substrate surrounding via interconnects at the periphery of a die to create a standoff between mismatched materials and the resulting device are provided. Embodiments include providing a substrate including one or more dies; providing via interconnects at a periphery of at least one die; and forming parallel trenches in the substrate on opposite sides of each via interconnect.

### TECHNICAL FIELD

The present disclosure relates to device wafer packaging. The present disclosure is particularly applicable to joining components with coefficient of thermal expansion (CTE) mismatches.

### BACKGROUND

The effects of CTE mismatch are well known in the packaging industry for causing high stresses in solder joints and other interfaces that are required to maintain electrical interconnection between the mismatched materials. For example, whereas the CTE for silicon is only 3 ppm, the CTEs for stainless steel and aluminum are 11 to 18 ppm and 23 ppm, respectively. Even if the joint is strong enough to withstand a few thermal cycles, such as those imposed by a solder reflow joining process, the risk of fatigue failure still exists as the device endures subsequent thermal cycles even at lower temperatures. This severely limits the choice of materials that can be used as a carrier substrate for attaching a silicon (Si) chip, since the CTE numbers need to be closely matched. It also limits the sizes of the chips that can be attached, since the amount of mismatch increases with distance from the neutral center point.

The aforementioned limitations can be partially mitigated by using highly compliant materials such as plastic, but the disadvantages of plastic materials are numerous, including, but not limited to, poor temperature resistance, poor structural integrity, and poor heat dissipating characteristics. An anisotropic conductive film (ACF)/anisotropic conductive paste (ACP)/anisotropic conductive adhesive (ACA) stack is an option for the concept of utilizing a compliant layer, but it is also limited by connection density. Copper (Cu) pillars may be utilized to achieve a larger gap, but their mechanical benefits are crippled by the fact that adhesion between the pillar and the substrate is never as strong as the substrate material itself. Also, the interface is always at the highest point of stress.

A need therefore exists for methodology enabling a standoff between mismatched materials and a reduction of the stress induced by displacement from expansion and contraction, and the resulting device.

### SUMMARY

An aspect of the present disclosure is a method of forming parallel trenches or slots into a substrate surrounding via interconnects at the periphery of a die to create a standoff between mismatched materials.

Another aspect of the present disclosure is a device including a substrate having parallel trenches or slots formed on opposite sides of via interconnects at the periphery of a die.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a substrate including one or more dies; providing via interconnects at a periphery of at least one die; and forming parallel trenches in the substrate on opposite sides of each via interconnect.

Aspects of the present disclosure include forming the trenches in the substrate in one direction. Other aspects include forming the trenches in the substrate in two directions, perpendicular to each other. Further aspects include forming each of the trenches to a length ranging from a length of the at least one die to a length of the entire substrate. Another aspect includes forming each of the trenches with a width of a dicing blade to 80% of a pitch between two adjacent via interconnects. Additional aspects include forming each of the trenches to a depth of 20% to 80% of a depth of the substrate. Other aspects include forming each of the trenches with rounded bottom edges. Further aspects include forming the trenches by dicing, deep reactive ion etching (DRIE), or laser etching.

Another aspect of the present disclosure is a device including: a substrate including one or more dies; via interconnects formed at a periphery of the at least one die; and parallel trenches formed in the substrate on opposite sides of each via interconnect.

Aspects of the device include the trenches being formed in the substrate in one direction. Other aspects include the trenches being formed in the substrate in two directions, perpendicular to each other. Further aspects include each of the trenches being formed with a length ranging from a length of the at least one die to a length of the entire substrate. Another aspect includes each of the trenches being formed with a width of a dicing blade to 80% of a pitch between two adjacent via interconnects. Additional aspects include each of the trenches being formed to a depth of 20% to 80% of a depth of the substrate. Other aspects include each of the trenches being formed with rounded bottom edges. Further aspects include the trenches being formed by dicing, DRIE, or laser etching.

A further aspect of the present disclosure is a method including: providing a substrate including one or more dies; providing via interconnects at a periphery of at least one die; and forming parallel trenches with rounded bottom edges in one or two directions in the substrate on opposite sides of each via interconnect.

Aspects of the present disclosure include forming each of the trenches to a length ranging from a length of the at least one die to a length of the entire substrate. Other aspects include forming each of the trenches with a width of a dicing blade to 80% of a pitch between two adjacent via interconnects. Further aspects include forming each of the trenches to a depth of 20% to 80% of a depth of the substrate.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B schematically illustrate a top view and a cross-sectional view, respectively, of a carrier substrate having one dimensional (1D) and two dimensional (2D) trench patterning, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of high stresses in solder joints, shorts caused by solder bridging, limited carrier substrate materials that avoid such stresses and shorts, and the expense of the underfill process step attendant upon attaching a Si chip to a carrier substrate.

Methodology in accordance with embodiments of the present disclosure includes providing a substrate including one or more dies. Via interconnects are provided at a periphery of at least one die. Parallel trenches are formed in the substrate on opposite sides of each via interconnect.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

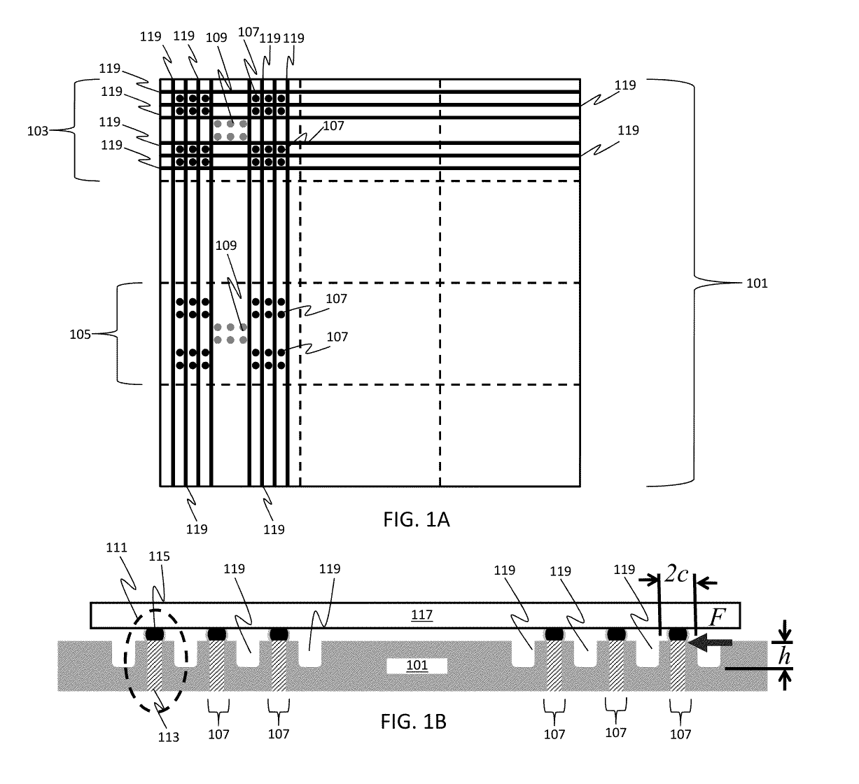

Adverting to FIGS. 1A and 1B, a carrier substrate 101 is provided including one or more dies, e.g., dies 103 and 105, the boundaries of each die depicted with dashed lines. Each die is also provided with via interconnects 107 at a periphery of a die, e.g., dies 103 and 105. In some instances, the dies 103 and 105 may also have via interconnects 109 located at the center of the respective dies 103 and 105. The via interconnects 107 and 109, as shown by the dashed oval 111 in FIG. 1B, are actually formed of a via 113 and an interconnect 115 between the via and a bare Si flip chip die 117. Parallel trenches 119 are then formed on opposite sides of each via interconnect 107. The parallel trenches 119 are not formed on opposite sides of a via interconnect 109 at the center of dies 103 and 105, for example, because stress is naturally low in the neutral zone or the center of the die. Accordingly, a die without via interconnects 109 may still benefit from parallel trenches 119 being formed on opposite sides of each via interconnect 107.

The parallel trenches 119 can be formed in one direction as depicted with respect to die 105 and/or in two directions, perpendicular to each other, as depicted with respect to die 103. The parallel trenches 119 may be formed, for example, to a length ranging from a length of one die to a length of the entire substrate and with a width of a dicing blade, e.g., 15 micrometers (μm), to a width of 80% of a pitch between two adjacent via interconnects 107. A typical interconnect pitch may range, for example, from 50 μm to 500 μm. The trenches 119 may also be formed with a pitch equal to the interconnect pitch. However, if the interconnect pitch is very wide, two trenches may be used to isolate the dead zone where no interconnects are present. The parallel trenches 119 may be formed, for example, to a depth 20% to 80% of a depth of the substrate 101, e.g., leaving 20 μm of material remaining for a 100 μm thick substrate. In general, a deeper parallel trench 119 is preferred as long as the substrate 101 remains intact.

The parallel trenches 119 are also formed with rounded bottom edges or fillet edges, as depicted in FIG. 1B. The rounded edges are formed when cutting the trench (either by the rounded edge of a dicing blade or naturally at the end of a dry etch process). Any amount of rounding provides significant reduction of stress concentration. In contrast, a standoff created by additive processing, e.g., a solder ball or Cu pillar, results in atomically sharp corners at the bottom of the pillar, which are very high stress concentrators and crack initiation points. Consequently, the parallel trenches 119 provide “flex” in the substrate 101 without any stress concentration points so that remaining weak-points do not ensure high stress.

Further, the formation of the parallel trenches 119 may depend, for example, on the material of the substrate 101. For a steel substrate, the parallel trenches 119 may be formed, for example, by abrasively dicing or laser dicing the parallel trenches 119. For an aluminum substrate 101, the parallel trenches 119 may be formed, for example, by dicing or dry etching, e.g., with chlorine (Cl₂), carbon tetrachloride (CCl₄), silicon tetrachloride (SiCl₄), or boron trichloride (BCl₃). In contrast, for a glass substrate 101, the parallel trenches 119 may be formed, for example, by dry etching with tetrafluoromethane (CF₄), sulfur hexafluoride (SF₆), or nitrogen trifluoride (NF₃). The parallel trenches 119 may also be formed, for example, by DRIE. Other possible materials for the substrate 101 include nickel-based alloys, such as Kovar and Invar.

The embodiments of the present disclosure can achieve several technical effects including substantially widening the choice of useable materials by allowing a substrate such as metal with a relatively high CTE to behave effectively more compliant like a plastic material. Other improvements include creating a standoff between the mismatched materials and exponentially reducing the stress induced by displacement from expansion and contraction. The stress can also be roughly modelled using the cantilever beam formulas: F=3×E×I×delta/h³ and σ=F×h×c/I, where I=area moment of inertia and h=gap. Also, the base of the standoff, or the point of highest stress, remains as strong as the substrate material itself. In addition, since the standoff is the same material as the base, and a fillet can be formed at the base, the effects of stress concentration are minimized. Furthermore, due to the reduction in stress, the underfill process step can be eliminated from the process flow, which in turn leads to significant cost savings. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial application in any of various types of semiconductor devices, particularly those with joined components having CTE mismatches.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a substrate including one or more dies;
providing via interconnects at a periphery of at least one die; and
forming parallel trenches in the substrate on opposite sides of each via interconnect.

2. The method according to claim 1, comprising forming the trenches in the substrate in one direction.

3. The method according to claim 1, comprising forming the trenches in the substrate in two directions, perpendicular to each other.

4. The method according to claim 1, comprising forming each of the trenches to a length ranging from a length of the at least one die to a length of the entire substrate.

5. The method according to claim 1, comprising forming each of the trenches with a width of a dicing blade to 80% of a pitch between two adjacent via interconnects.

6. The method according to claim 1, comprising forming each of the trenches to a depth of 20% to 80% of a depth of the substrate.

7. The method according to claim 1, comprising forming each of the trenches with rounded bottom edges.

8. The method according to claim 1, comprising forming the trenches by dicing, deep reactive ion etching (DRIE), or laser etching.

9. A device comprising:
a substrate including one or more dies;
via interconnects formed at a periphery of the at least one die; and
parallel trenches formed in the substrate on opposite sides of each via interconnect.

10. The device according to claim 9, wherein the trenches are formed in the substrate in one direction.

11. The device according to claim 9, wherein the trenches are formed in the substrate in two directions, perpendicular to each other.

12. The device according to claim 9, wherein each of the trenches has a length ranging from a length of the at least one die to a length of the entire substrate.

13. The device according to claim 9, wherein each of the trenches is formed with a width of a dicing blade to 80% of a pitch between two adjacent via interconnects.

14. The device according to claim 9, wherein each of the trenches is formed to a depth of 20% to 80% of a depth of the substrate.

15. The device according to claim 9, wherein each of the trenches is formed with rounded bottom edges.

16. The device according to claim 9, wherein the trenches are formed by dicing, deep reactive ion etching (DRIE), or laser etching.

17. A method comprising:
providing a substrate including one or more dies;
providing via interconnects at a periphery of at least one die; and
forming parallel trenches with rounded bottom edges in one or two directions in the substrate on opposite sides of each via interconnect.

18. The method according to claim 17, comprising forming each of the trenches to a length ranging from a length of the at least one die to a length of the entire substrate.

19. The method according to claim 17, comprising forming each of the trenches with a width of a dicing blade to 80% of a pitch between two adjacent via interconnects.

20. The method according to claim 17, comprising forming each of the trenches to a depth of 20% to 80% of a depth of the substrate.
